(19) United States
(12) Patent Application Publication
(10) Pub. No.: US 2026/0129793 A1
(43) Pub. Date: May 7, 2026

(54) CLOSED-LOOP LIQUID COOLER WITH PIN-FINS

(71) Applicant: AMULAIRE THERMAL TECHNOLOGY, INC., New Taipei City (TW)

(72) Inventors: CHING-MING YANG, New Taipei City (TW); KUO-WEI LEE, New Taipei City (TW); TZE-YANG YEH, New Taipei City (TW); MING-HSUAN CHANG, Taoyuan City (TW)

(21) Appl. No.: 18/935,831

(22) Filed: Nov. 4, 2024

(51) Int. Cl. H05K 7/20

(52) U.S. Cl. CPC H05K 7/20263

(57) ABSTRACT

A closed-loop liquid cooler with pin-fins is provided, which includes a first external cover, a second cover, a plurality of water holes, a liquid channel, and a plurality of pin-fins. The water holes are formed on at least one of the first external cover and the second external cover. The liquid channel is formed between the first external cover and the second external cover, and is in spatial communication with the water holes. The pin-fins are located in the liquid channel. At least a portion of the pin-fins are copper fins made by copper or copper alloy. At least another portion of the pin-fins are aluminum fins made by aluminum or aluminum alloy. At least one of diameters, inscribed circle diameters, width, spacing, heights, shapes and draft angles of the copper fins and the aluminum fins are different.

### FIELD OF THE DISCLOSURE

The present disclosure relates to a liquid cooler, and more particularly to a closed-loop liquid cooler with pin-fins.

### BACKGROUND OF THE DISCLOSURE

Liquid coolers for automotive IGBT (insulated gate bipolar transistor) or ADAS (advanced driver assistance system) that are currently available on the market need to meet higher and higher requirements. However, the heat dissipation performance of aluminum liquid coolers is limited, and copper liquid coolers are costly and heavy, which forms a dilemma where existing liquid coolers are unable to satisfy such requirements.

### SUMMARY OF THE DISCLOSURE

In response to the above-referenced technical inadequacy the present disclosure provides a closed-loop liquid cooler with pin-fins.

In order to solve the above-mentioned problems, one of the technical aspects adopted by the present disclosure is to provide a closed-loop liquid cooler with pin-fins, which includes: a first external cover, a second external cover, a plurality of water holes, a liquid channel, and a plurality of pin-fins. The water holes are formed on at least one of the first external cover and the second external cover, the liquid channel is formed between the first external cover and the second external cover, and is in spatial communication with the water holes. The pin-fins are located in the liquid channel, at least a portion of the pin-fins are copper fins made by copper or copper alloy, and at least another portion of the pin-fins are aluminum fins made by aluminum or aluminum alloy. At least one of the following characteristics of the copper fins and the aluminum fins is different: the diameters, inscribed circle diameters, widths, spacing, heights, shapes and draft angles.

In one of the possible or preferred embodiments, a ratio of the height of the copper fin to the diameter, diagonal length, inscribed circle diameter, width, or minor circle diameter of the copper fin is configured to be between 1.5 to 12.

In one of the possible or preferred embodiments, a value of the diameter, diagonal length, inscribed circle diameter, width, or minor circle diameter of the aluminum fin is configured to be greater than 3 mm, and the height of the aluminum fins is configured to be less than 30 mm.

In one of the possible or preferred embodiments, a value of the diameter, diagonal length, inscribed circle diameter, width, or minor circle diameter of the copper fin is configured to be greater than or equal to 1 mm.

In one of the possible or preferred embodiments, a minimum distance between top ends of any two adjacent copper fins is configured to be between 0.5 to 5 mm, and a minimum distance between top ends of any two adjacent aluminum fins is configured to be greater than 3 mm.

In one of the possible or preferred embodiments, the aluminum fins are integrally formed on a plate body of the second external cover, and a thickness of the second external cover is greater than 3 mm.

In one of the possible or preferred embodiments, the aluminum fins and the second external cover are a die cast aluminum alloy component formed by die casting.

In one of the possible or preferred embodiments, the copper fins are integrally formed on a copper base which is coupled to the second external cover.

In one of the possible or preferred embodiments, the copper fins and the copper base are a forged copper alloy component formed by forging.

In one of the possible or preferred embodiments, the draft angle of the copper fins is greater than 0.4 degrees, and the draft angle of the aluminum fins is greater than 1.5 degrees.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a liquid cooler according to the present disclosure;

FIG. 2 is a schematic view of an inside of the liquid cooler according to the present disclosure;

FIG. 3 is a schematic cross-sectional view taken along line III-III of FIG. 2;

FIG. 4 is a schematic top view of copper fins of the liquid cooler according to the present disclosure;

FIG. 5 is another schematic top view of the copper fins of the liquid cooler according to the present disclosure;

FIG. 6 is another schematic top view of the copper fins of the liquid cooler according to the present disclosure;

FIG. 7 is another schematic top view of the copper fins of the liquid cooler according to the present disclosure;

FIG. 8 is another schematic top view of the copper fins of the liquid cooler according to the present disclosure;

FIG. 9 is a schematic top view of aluminum fins of the liquid cooler according to the present disclosure;

FIG. 10 is another schematic top view of the aluminum fins of the liquid cooler according to the present disclosure;

FIG. 11 is another schematic top view of the aluminum fins of the liquid cooler according to the present disclosure;

FIG. 12 is another schematic top view of the aluminum fins of the liquid cooler according to the present disclosure; and

FIG. 13 is another schematic top view of the aluminum fins of the liquid cooler according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on. ” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiment

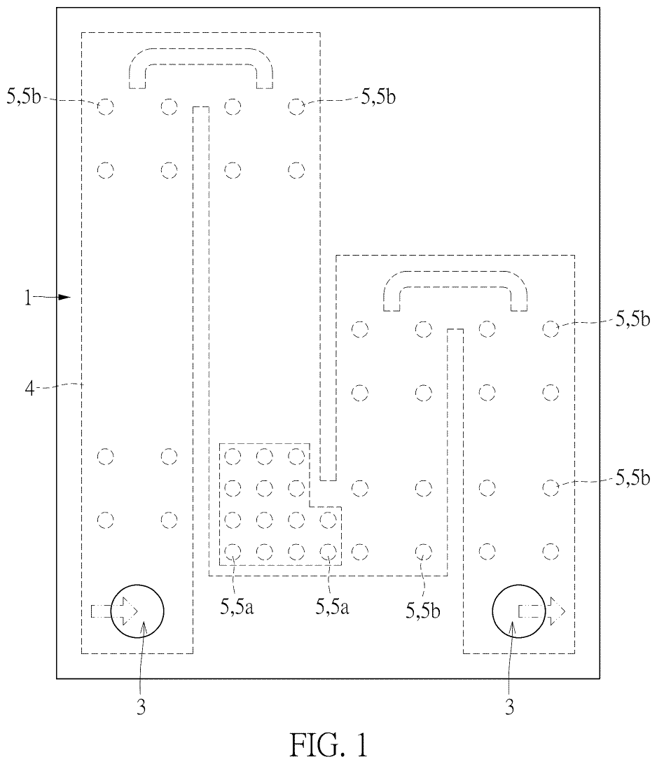

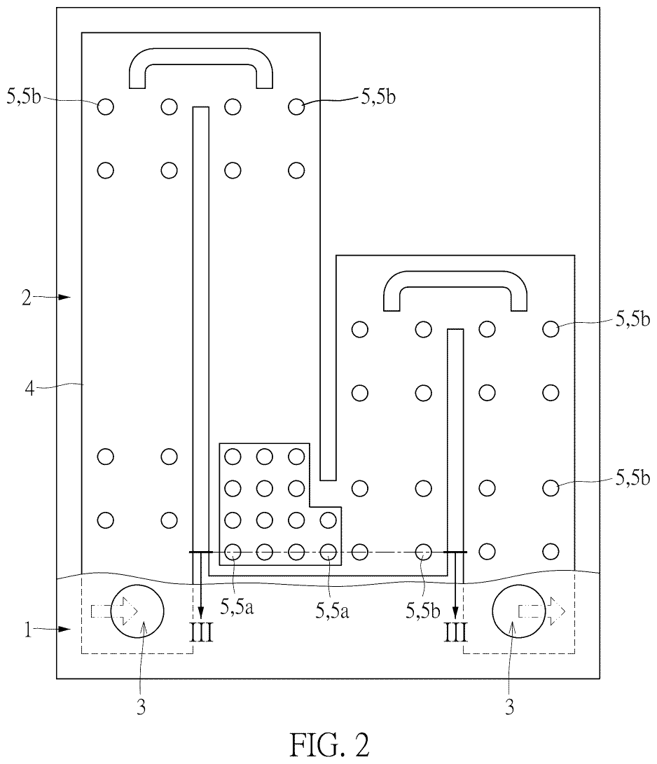

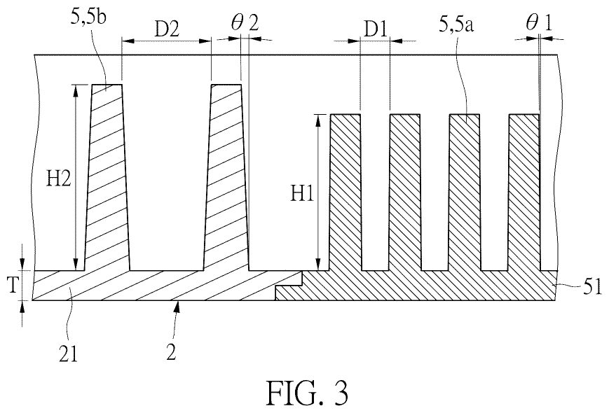

Reference is made to FIG. 1, FIG. 2, and FIG. 3, which show an embodiment of the present disclosure. The present embodiment of the present disclosure provides a closed-loop liquid cooler with pin-fins. The closed-loop liquid cooler with pin-fins provided according to the present embodiment of the present disclosure includes a first external cover 1, a second external cover 2, a plurality of water holes 3, a liquid channel 4, and a plurality of pin-fins 5.

The first external cover 1 and the second external cover 2 can be made from aluminum or aluminum alloy. In the present embodiment, the first external cover 1 can be an upper cover, and the second external cover 2 can be a lower cover. The water holes 3 are formed on at least one of the first external cover 1 and the second external cover 2. In the present embodiment, two water holes 3 are formed on the first external cover 1, but it is also possible that one water hole is formed on the first external cover 1, and another one is formed on the second external cover 2; or that the two water holes 3 are formed on the second external cover 2, the present disclosure not being limited therein. Moreover, one of the water holes 3 can be a water inlet hole, and another water hole 3 can be a water outlet hole.

The liquid channel 4 is formed between the first external cover 1 and the second external cover 2 in a curved shape and is in spatial communication with the two water holes 3, such that the cooling liquid (water or ethylene glycol) can enter the liquid channel 4 through one of the water holes 3, and can exit the liquid channel 4 through another one of the water holes 3.

The pin-fins 5 are located in the liquid channel 4. Among these pin-fins 5, at least a portion thereof are copper fins 5a made from copper or copper alloy, and at least another portion thereof are aluminum fins 5b made from aluminum or aluminum alloy. At least one of the diameter, inscribed circle diameter, width, spacing, height, shape, and draft angle of the copper fins 5a and aluminum fins 5b are different. In this way, the liquid channel 4 of the closed-loop liquid cooler provided by the present embodiment has a plurality of pin-fins 5, and at least a portion of the pin-fins are copper fins 5a, and at least another portion of the pin-fins are aluminum fins 5b. By the structural design that at least one of the diameters, inscribed circle diameters, widths, spacing, heights, shapes, and draft angles of the copper fins 5a and the aluminum fins 5b are different, limitations on the heat dissipating ability of aluminum liquid coolers can be effectively improved, and lower costs and lighter weight can be achieved compared with copper liquid coolers.

In particular, as shown in FIG. 3, the height H1 of the copper fins 5a can be configured to be 6 mm, and the copper fins 5a can be integrally formed on a copper base 51, which is coupled to the second external cover 2. The copper fins 5a and the copper base 51 can be a forged copper alloy component formed by forging, or can be formed by metal injection molding. The height H2 of the aluminum fins 5b can be configured to be less than 30 mm, and the aluminum fins 5b can be integrally formed on the plate body 21 of the second external cover 2, with the thickness T of the plate body 21 of the second external cover 2 greater than 3 mm. The aluminum fins 5b and the second external cover 2 can be a die cast aluminum alloy component formed by die casting.

Furthermore, the minimum distance D1 between the top of any two adjacent copper fins 5a is configured to be between 0.5 to 5 mm, and the minimum distance D2 between the top of any two adjacent aluminum fins 5b is configured to be greater than 3 mm. Preferably, the minimum distance D2 between the top of any two adjacent aluminum fins 5b should be greater than the minimum distance D1 between the top of any two adjacent copper fins 5a, such that the aluminum fins 5b and the copper fins 5a have different arrangement densities. In this way, by reducing the quantity of the aluminum fins 5b in non-heat-source region or increasing the spacing to reduce the arrangement density, it becomes easier to form the aluminum fins 5b by die casting. On the other hand, by increasing the quantity of the copper fins 5a in the heat source region or reducing the spacing to increase the arrangement density, the ability of heat dissipation can be improved. That is, the heat dissipation performance in the heat source region can be better, and the overall temperature of the non-heat-source region can be more uniform. Apart from accelerating the flow speed of the cooling liquid flowing through the non-heat-source region, the temperature of the cooling liquid flowing through the heat source region can also be prevented from being too high.

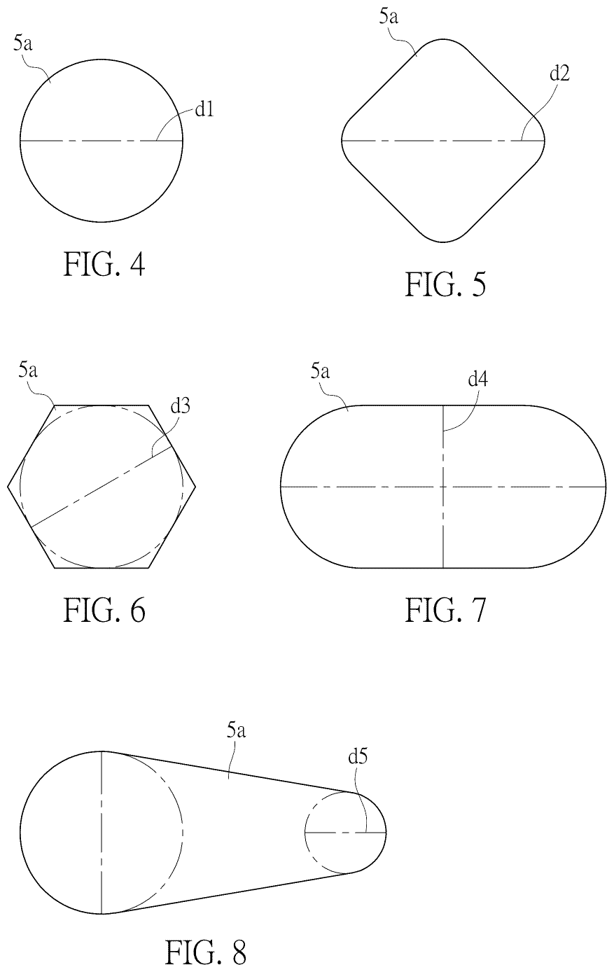

Reference is made to FIG. 4 along with FIG. 3. In one example, the shape of the top of the copper fin 5a is round, and the ratio between the height H1 of the copper fin 5a and the diameter d1 of the top of the copper fin 5a is configured to be between 1.5 to 12. In particular, the diameter d1 of the top of the copper fin 5a is configured to be greater than or equal to (≥) 1 mm. The diameter d1 of the top of the copper fin 5a can be 2 mm. In addition, the draft angle θ1 of the copper fin 5a can be greater than 0.4 degrees.

Reference is made to FIG. 5 along with FIG. 3. In one example, the shape of the top of the copper fin 5a is rhombus, and the ratio between the height H1 of the copper fin 5a and the diagonal length d2 of the top of the copper fin 5a is configured to be between 1.5 to 12. In particular, the diagonal length d2 of the top of the copper fin 5a is configured to be greater than or equal to 1 mm. The diagonal length d2 of the top of the copper fin 5a can be 2 mm.

Reference is made to FIG. 6 along with FIG. 3. In one example, the shape of the top of the copper fin 5a is hexagonal, and the ratio between the height H1 of the copper fin 5a and the inscribed circle diameter d3 of the top of the copper fin 5a is configured to be between 1.5 to 12. In particular, the inscribed circle diameter d3 of the top of the copper fin 5a is configured to be greater than or equal to 1 mm. The inscribed circle diameter d3 of the copper fin 5a can be 2 mm.

Reference is made to FIG. 7 along with FIG. 3. In one example, the shape of the top of the copper fin 5a is oval, and the ratio between the height H1 of the copper fin 5a and the width d4 of the top of the copper fin 5a is configured to be between 1.5 to 12. In particular, the width d4 of the top of the copper fin 5a is configured to be greater than or equal to 1 mm. The width d4 of the top of the copper fin 5a can be 2 mm.

Reference is made to FIG. 8 along with FIG. 3. In one example, the shape of the top of the copper fin 5a is drop-shaped, and the ratio between the height H1 of the copper fin 5a and the minor circle diameter d5 of the top of the copper fin 5a is configured to be between 1.5 to 12. In particular, the minor circle diameter d5 of the top of the copper fin 5a is configured to be greater than or equal to 1 mm. The minor circle diameter d5 of the top of the copper fin 5a can be 1 mm.

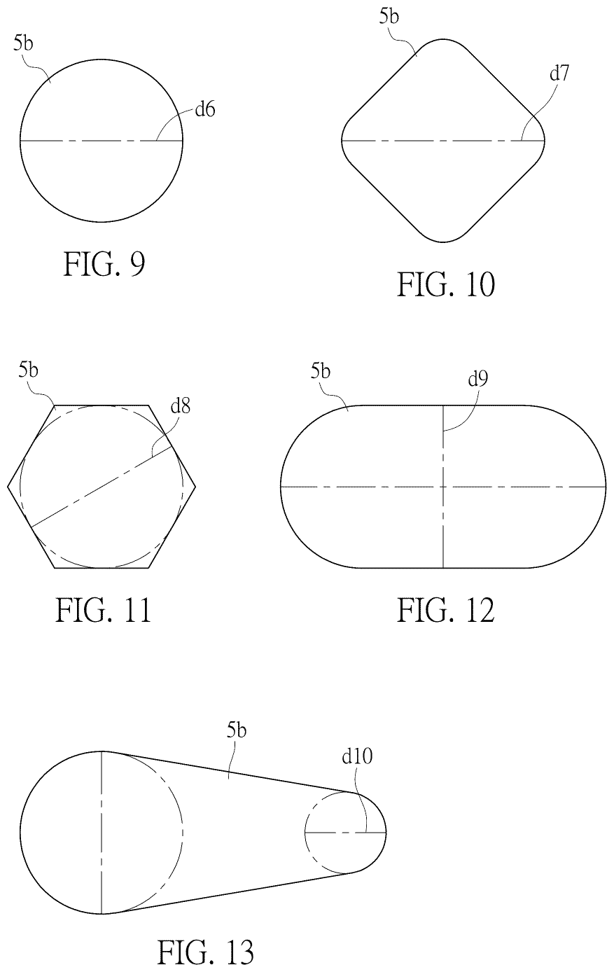

Reference is made to FIG. 9 along with FIG. 3. In one example, the shape of the top of the aluminum fin 5b is round, and the diameter d6 of the top of the aluminum fins 5b is configured to be greater than 3 mm. In addition, the draft angle θ2 of the aluminum fin 5b can be greater than 1.5 degrees.

Reference is made to FIG. 10 along with FIG. 3. In one example, the shape of the top of the aluminum fin 5b is a rhombus, and the diagonal length d7 of the top of the aluminum fin 5b is configured to be greater than 3 mm.

Reference is made to FIG. 11 along with FIG. 3. In one example, the shape of the top of the aluminum fin 5b is hexagonal, and the inscribed circle diameter d8 of the top of the aluminum fin 5b is configured to be greater than 3 mm.

Reference is made to FIG. 12 along with FIG. 3. In one example, the shape of the top of the aluminum fin 5b is oval, and the width d9 of the top of the aluminum fin 5b is configured to be greater than 3 mm.

Reference is made to FIG. 13 along with FIG. 3. In one example, the shape of the top of the aluminum fin 5b is drop-shaped, and the minor circle diameter d10 of the aluminum fin 5b is configured to be greater than 3 mm.

However, the aforementioned details are disclosed for exemplary purposes only, and are not meant to limit the scope of the present disclosure.

### Beneficial Effects of the Embodiment

In conclusion, the closed-loop liquid cooler with pin-fins provided by the present disclosure includes a first external cover, a second external cover, a plurality of water holes, a liquid channel, and a plurality of pin-fins. The water holes are formed on at least one of the first external cover and the second external cover. The liquid channel is formed between the first external cover and the second external cover and is in spatial communication with the water holes. The pin-fins are located in the liquid channel. At least a portion of the pin-fins are copper fins made from copper or copper alloy. At least another portion of the pin-fins are aluminum fins made from aluminum or aluminum alloy. At least one of the diameter, inscribed circle diameter, width, spacing, height, shape and draft angle of the copper fins and the aluminum fins is different. In this way, by virtue of “the liquid channel of the closed-loop liquid cooler of the present disclosure having a plurality of pin-fins,” “at least a portion of the ping-fins being copper fins, and at least another portion of the pin-fins being aluminum fins,” and “at least one of the diameter, inscribed circle diameter, width, spacing, height, shape, and draft angle of the copper fins and the aluminum fins being different,” limitations on the heat dissipating ability of aluminum liquid coolers can be effectively improved, and the liquid cooler of the present disclosure can have lower costs and lighter weight.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A closed-loop liquid cooler with pin-fins, comprising:
a first external cover;
a second external cover;
a plurality of water holes;
a liquid channel; and
a plurality of pin-fins;
wherein the water holes are formed on at least one of the first external cover and the second external cover, the liquid channel is formed between the first external cover and the second external cover, and is in spatial communication with the water holes; wherein the pin-fins are located in the liquid channel, at least a portion of the pin-fins are copper fins made from copper or copper alloy, and at least another portion of the pin-fins are aluminum fins made from aluminum or aluminum alloy; wherein at least one of following properties of the copper fins and the aluminum fins is different: diameter, inscribed circle diameter, width, spacing, height, shapes and draft angle.

2. The closed-loop liquid cooler according to claim 1, wherein a ratio of the height of the copper fin to the diameter, diagonal length, inscribed circle diameter, width, or minor circle diameter of the copper fin is configured to be between 1.5 to 12.

3. The closed-loop liquid cooler according to claim 2, wherein a value of the diameter, diagonal length, inscribed circle diameter, width, or minor circle diameter of the aluminum fin is configured to be greater than 3 mm, and the height of the aluminum fin is configured to be less than 30 mm.

4. The closed-loop liquid cooler according to claim 2, wherein a value of the diameter, diagonal length, inscribed circle diameter, width, or minor circle diameter of the copper fin is configured to be greater than or equal to 1 mm.

5. The closed-loop liquid cooler according to claim 1, wherein a minimum distance between top ends of any two adjacent copper fins is configured to be between 0.5 to 5 mm, and a minimum distance between top ends of any two adjacent aluminum fins is configured to be greater than 3 mm.

6. The closed-loop liquid cooler according to claim 1, wherein the aluminum fins are integrally formed on a plate body of the second external cover, and a thickness of the second external cover is greater than 3 mm.

7. The closed-loop liquid cooler according to claim 6, wherein the aluminum fins and the second external cover are a die cast aluminum alloy component formed by die casting.

8. The closed-loop liquid cooler according to claim 1, wherein the copper fins are integrally formed on a copper base which is coupled to the second external cover.

9. The closed-loop liquid cooler according to claim 8, wherein the copper fins and the copper base are a forged copper alloy component formed by forging.

10. The closed-loop liquid cooler according to claim 1, wherein the draft angle of the copper fins is greater than 0.4 degrees, and the draft angle of the aluminum fins is greater than 1.5 degrees.
